(19) United States
(12) Patent Application Publication
(10) Pub. No.: US 2009/0121147 A1
(43) Pub. Date: May 14, 2009

(54) DETECTION APPARATUS AND METHOD FOR USE WITH BIOSENSOR EMITTING RF SIGNALS

(75) Inventor: Josephus Arnoldus Henricus Maria KAHLMAN, Tilburg (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/718,252

(22) PCT Filed: Oct. 24, 2005
(86) PCT No.: PCT/IB05/53462

§ 371 Date: Apr. 30, 2007

(30) Foreign Application Priority Data
Nov. 5, 2004 (EP) 04105555.9

(51) Int. Cl. G01R 29/08

(52) U.S. Cl. 250/395; 250/336.1

(57) ABSTRACT

A detecting apparatus (2) for determining the presence and/or concentration of a predetermined biomolecule on a biosensor (4) is disclosed. The biosensor (4) emits radio frequency radiation in response to irradiation of a photodiode (8) by laser light, and has a resonant circuit having a resonant frequency dependent upon the presence and/or concentration of the relevant biomolecule on the sensor (4). The apparatus (2) comprises a laser diode (12) irradiating the sensor (4), and a receiver (20, 22) for receiving RF radiation emitted by the sensor (4) and providing an output signal representing the frequency deviation in RP radiation emitted by the sensor (4) caused by the presence and/or changes in concentration of the biomolecule. Integrators (26, 38), multiplier (32) and adder (28) reduce the dependency of the frequency deviation signal on the output intensity of the laser diode (12).

The present invention relates to an apparatus and method for detecting the presence of a predetermined substance on a sensor. The invention relates particularly, but not exclusively, to an apparatus and method for detecting biomolecules by means of biosensors which emit radio frequency radiation in response to irradiation by laser light.

Biosensors are used to determine the presence and/or concentration of bio-molecules in fluids. The biosensor has a sensor element having binding sites for a biomolecule, such that a signal is caused by interaction of the binding site on a sensor surface with biochemical components in a fluid. Typically, a fluid component binds specifically to molecules forming the bonding sites on a surface of the sensor element. Examples of biomolecules are proteins, peptides, nucleic acids, carbohydrates and lipids. Examples of fluids are simple buffers and biological fluids, such as blood, serum, plasma, saliva, urine or tissue homogenates.

In a biosensor cartridge, a sensor element is provided with bonding sites. To facilitate detection, markers or labels are often used, for example small beads, nanoparticles, or special molecules having certain fluorescent or magnetic properties. Labels can be attached before or after the analyte (i.e. the molecules to be determined) binds to the sensor. Microparticles are sometimes used as a solid phase to capture the analyte. Solid phase microparticles can be made from a variety of materials, such as glass, plastic or latex, depending upon the particular application. Some solid phase particles are made from ferromagnetic materials to facilitate their separation from complex suspensions or mixtures. The occurrence of a binding reaction, binding the solid phase microparticles (or some other marker which has captured the analyte) can be detected, for example by fluorescent markers.

The sensing of the molecules in the sensor is known as assay. Such assays have various formats, for example binding, sandwich assay, competitive assay, and displacement assay. In conventional solid phase assays, the solid phase mainly aids in separating biomolecules that bind to the solid phase from molecules that do not. Separation can be facilitated by gravity, centrifugation, filtration, magnetism, flow-cytometry, microfluidics, etc. The separation may be performed either in a single step in the assay or, more usually, in multiple steps.

It is often desirable to perform two or more different assays on the same sample, in a single vessel and at about the same time. Such assays are known to persons skilled in the art as multiplex assays. Multiplex assays are performed to determine simultaneously the presence or concentration of more than one molecule in the sample being analysed or, alternatively, to evaluate several characteristics of a single molecule, such as the presence of several epitopes on a single protein molecule.

Biosensors are intended to be tools for doctors or laboratory personnel. Because of various strict rules in medical practice, the biosensor will only be used once, as a result of which it must be inexpensive and easy to operate.

An example of such a biosensor is disclosed in WO 2004/053491, in which a biosensor in the form of an electronic chip has a photodiode, and a resonant circuit, the resonant frequency of which varies as a result of variation in the inductance, capacitance or resistance of a component of the resonant circuit caused by binding of biomolecules at binding sites of that component. For example, the component may be a flat coil in the surface of the sensor, the inductance of which changes as a result of binding of ferromagnetic beads to the coil. The presence of such biomolecules is determined by detecting radio frequency radiation emitted by the biosensor as a result of irradiation of the photodiode of the biosensor with laser light.

Although biosensors of this type are easier to obtain accurate data from than sensors relying on fluorescent behaviour, they suffer from the drawback that as well as being dependent upon the presence and/or concentration of the biomolecule being detected, the resonant frequency of the resonant circuit also depends upon the intensity of the laser light source irradiating the photodiode of the biosensor. This results in the accuracy of any measurement using the biosensor being either significantly limited, or signal processing components must be added to the sensor chip, which significantly increases the cost and the size of the sensor. This is a significant disadvantage, since biosensors of this type are typically disposable products intended for single use. In addition, accuracy of measurements using the sensor is limited by process tolerances of the integrated circuit manufacturing processes used to manufacture the biosensors, and on-chip frequency stabilisation components must be added, which also increases the cost of production of the biosensor.

Preferred embodiments of the present invention seek to enable the production of biosensors at lower cost.

According to an aspect of the present invention, there is provided an apparatus for detecting the presence and/or concentration of a predetermined substance on a sensor adapted to emit electromagnetic radiation of at least one first frequency in response to irradiation by electromagnetic radiation of at least one second frequency such that at least one said first frequency is dependent upon the presence and/or concentration of said predetermined substance, the apparatus comprising:

a radiation source for irradiating a sensor with electromagnetic radiation;

a receiver for receiving electromagnetic radiation emitted by said sensor;

detector means for providing an output signal dependent upon the change in at least one said first frequency caused by the presence and/or changes in concentration of said predetermined substance on the sensor; and

adjustment means for reducing dependency of said output signal on the output intensity of said radiation source.

By providing adjustment means forming part of the apparatus for reducing dependency of said output signal on the output intensity of the radiation source, this provides the advantage of avoiding the necessity of providing components on the sensor which adjust the resonant frequency of the sensor to compensate for variations in output intensity of the radiation source. This in turn provides the advantage of enabling sensors of lower cost to be manufactured.

The adjustment means may be adapted to adjust said detector means to adjust at least one said first frequency corresponding to said output signal.

The adjustment means may be adapted to adjust said output signal.

The adjustment means may be adapted to adjust the output intensity of said radiation source.

This provides the advantage of enabling the operating frequency of the system to be tuned to the most advantageous frequency in terms of interfering signals and signal to noise ratio, as well as avoiding the necessity of providing signal processing components on the sensor, thus minimising the cost of production of the sensor.

The adjustment means may be adapted to provide an adjustment signal representing dependency of said output signal on the output intensity of said radiation source.

The adjustment means may be adapted to suppress fluctuations in said output signal.

This provides the advantage of enabling fluctuations caused by noise to be reduced.

The adjustment means may include first integrating means for integrating said output signal.

The adjustment means may comprise second integrating means for integrating a signal representing variations in said output signal with the output intensity of said radiation source.

The apparatus may further comprise first stabilising means for reducing fluctuations in the frequency of the signal of maximum intensity detected by said detector means.

The apparatus may further comprise second stabilising means for reducing fluctuations in the frequency of the radiation of maximum intensity output by said radiation source.

The receiver may include an antenna and a radio frequency receiver.

According to another aspect of the present invention, there is provided a measurement system comprising an apparatus as defined above and a sensor adapted to emit electromagnetic radiation of at least one first frequency in response to irradiation by means of said radiation source.

According to a further aspect of the present invention, there is provided a method for determining the presence and/or concentration of a predetermined substance on a sensor adapted to emit electromagnetic radiation of at least one first frequency in response to irradiation by electromagnetic radiation of at least one second frequency such that at least one said first frequency is dependent upon the presence and/or concentration of said predetermined substance, the method comprising:

irradiating a sensor with electromagnetic radiation;

receiving electromagnetic radiation emitted by said sensor;

providing an output signal dependent upon the change in at least one said first frequency caused by the presence and/or changes in concentration of said predetermined substance on the sensor; and

reducing dependency of said output signal on the output intensity of said radiation source.

The method may comprise adjusting at least one said first frequency corresponding to said output signal.

The method may comprise adjusting said output signal.

The method may comprise adjusting the output intensity of said electromagnetic radiation irradiating said sensor.

The method may further comprise providing an adjustment signal representing dependency of said output signal on the output intensity of said electromagnetic radiation irradiating said sensor.

The method may further comprise reducing fluctuations in said output signal.

The method may include integrating said output signal.

The method may further comprise reducing fluctuations in the frequency of the signal of maximum intensity of detected electromagnetic radiation emitted by the sensor.

The apparatus may further comprise reducing fluctuations in the frequency of the radiation of maximum intensity irradiating the sensor.

Preferred embodiments of the invention will now be described, by way of example only and not in any limitative sense, with reference to the accompanying drawings, in which:

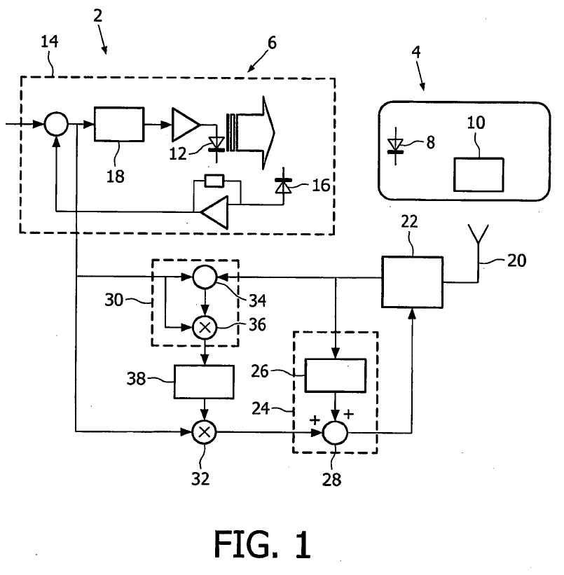

FIG. 1 is a schematic view of a detecting apparatus of a first embodiment of the invention during a calibration step, together with a biosensor;

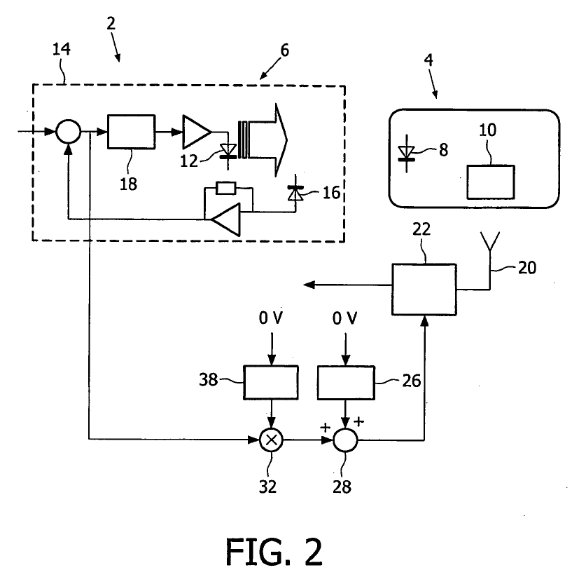

FIG. 2 is a schematic view of the apparatus of FIG. 1 during a measurement step;

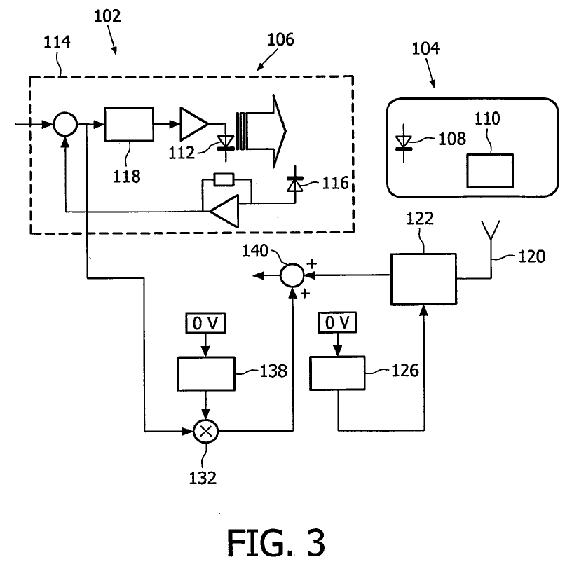

FIG. 3 is a schematic view of a second embodiment of the invention during a measurement step;

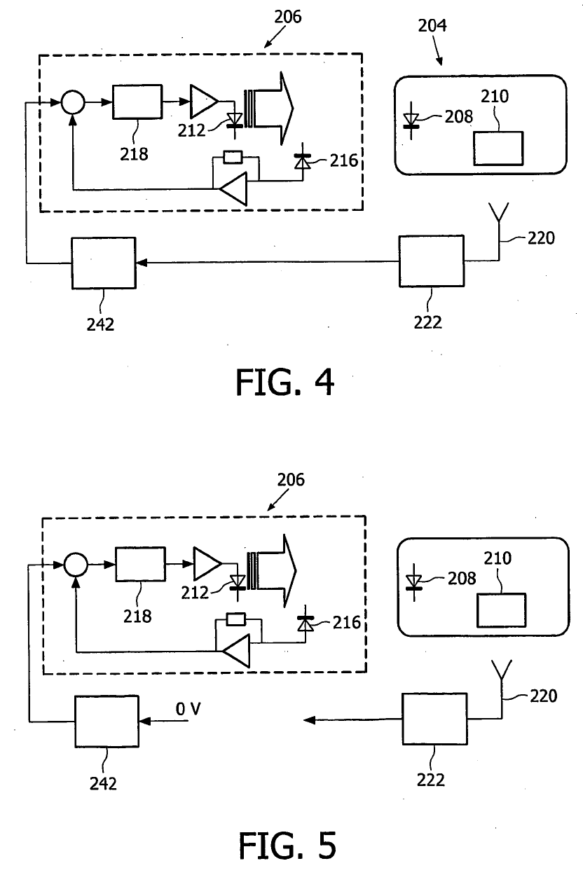

FIG. 4 is a schematic view of a third embodiment of the invention during a calibration step; and

FIG. 5 is a schematic view of the embodiment of FIG. 4 during a measuring step.

Referring to FIG. 1, a system 2 for determining the presence and/or concentration of a biomolecule in a test fluid comprises a biosensor 4 and a detecting apparatus 6. The sensor 4 is in the form of an electronic chip having a photovoltaic cell comprising a photo diode 8, a resonant circuit 10) powered by the photo diode 8, and an antenna (not shown) for enabling the sensor 4 to emit radio frequency radiation in response to irradiation of the photo diode by means of laser light from a light source in the form of a laser diode 12 on the detecting apparatus 6.

The resonant circuit on biosensor 4 is of the type disclosed in WO 2004/053491 and is constructed such that its resonant frequency is dependent upon the presence and/or concentration of the biomolecule being detected, for example as a result of bonded super paramagnetic dyna beads near to the surface of a coil of the resonant circuit causing an increase of the inductance of the coil and therefore a decrease of the resonant frequency of the resonant circuit.

The detecting apparatus 6 includes laser diode 12 for irradiating the sensor 4, the output power of the laser diode 12 being stabilised by means of a laser power regulation control loop 14 having a forward sense photodiode 16 and a loop filter 18. In this way, when the forward sense photodiode 16 detects changes in output intensity of the light emitted from laser diode 12, a control signal is generated to minimise fluctuations in the output of the laser diode 12.

The detecting apparatus 6 also includes an antenna 20 for receiving radio frequency radiation from the biosensor 4, and a tunable radio frequency receiver 22 for receiving input signals from the antenna 20 and producing an output signal representing the frequency deviation between the frequency of radiation received from the sensor 4 and the receive frequency of the receiver 22. Said frequency deviation is reduced to zero by means of an automatic frequency control loop 24 having a first integrator 26 and a first adder 28

The input signal to loop filter 18 represents variations in the output intensity of light emitted by laser diode 12, and is input to a correlator 30 and a first multiplier 32. The correlator includes a second adder 34 for determining the difference between the input signal of the loop filter 18 and the frequency deviation signal output by the receiver 22, and producing a difference signal which is passed together with the input of loop filter 18 to a second multiplier 36, the output of which is input to second integrator 38. The integrated output of second integrator 38 is input to first multiplier together with input signal of loop filter 18, and the output of the multiplier 32 is input to the adder 28 of frequency control loop 28 to adjust fine-tuning of the RF receiver 22.

The first integrator 26 can be used to generate an output signal representing the average frequency of RF radiation emitted by the sensor 4 over a period in which the output intensity of the laser diode 12 is held substantially constant. Similarly, the second integrator 38 can be used to generate a signal representing the dependence of the frequency variation signal output by receiver 22 upon fluctuations in the output intensity of laser diode 12.

The operation of the embodiment of FIG. 1 will now be described.

In a calibration step, the relationship between variations in the output intensity of the laser diode 12 and resulting changes in the frequency deviation signal output by receiver 22 when the sensor 4 is placed in a neutral liquid (i.e. not containing the biomolecule to be detected) is determined. This is achieved by integrating the output of correlator 30 over time to generate a signal at the output of integrator 38 representing a correlation factor between changes in the output intensity of laser diode 12 and changes in the frequency deviation signal output by receiver 22. This enables a suitable signal to be output from multiplier 32 to adjust the fine-tuning of receiver 22 in response to fluctuation in the output intensity of laser diode 12. In addition, the frequency deviation signal is used to stabilise the frequency deviation between the RF radiation and the receive frequency of receiver 22.

The measurement step shown in FIG. 2 is then carried out by holding the output of integrators 26, 38 constant so that the average offset signal is applied to multiplier 32 and adder 28, and the sensor 4 is placed in a test liquid for which the presence and/or concentration of the biomolecule of interest is to be determined. The presence of the relevant label or marker showing the presence of the biomolecule being detected, for example the presence of super para magnetic beads near the sensor, causes a reduction in the resonant frequency of the resonant circuit on sensor 4, as a result of which the frequency deviation signal output by receiver 22 represents the presence and/or concentration of the biomolecule. In this way, the system can be calibrated to compensate for variations in the output intensity of laser diode 12 without the necessity of providing costly on-chip signal processing components. The system also enables the necessary frequency lock between the sensor 4 and receiver 22 to be carried.

Referring now to FIG. 3, in which parts common to the embodiment of FIGS. 1 and 2 are denoted by like reference numerals but increased by 100, a further embodiment of the invention is shown. In the measuring step shown in FIG. 3, the output of integrator 126 is held constant to provide a fine-tuning signal to receiver 122. The output of integrator 138 is input to multiplier 132, and the input signal of loop filter 118 is input to the other input of multiplier 132. The output of multiplier 132 is input as a control signal to adder 140 to adjust the frequency deviation signal output by receiver 122 to take account of variations in the output intensity of the laser diode 112.

A further embodiment of the invention is shown in FIGS. 4 and 5, in which parts common to the embodiment of FIGS. 1 and 2 are denoted by like reference numerals but increased by 200. Referring firstly to FIG. 4, in a calibration step, the output intensity of the laser diode 212 is controlled via the frequency deviation signal of the RF receiver 22 to cause the biosensor chip 204 to oscillate at the centre frequency of the receiver 222. To enable the chip to operate in a region giving a favourable signal-to-noise ratio and/or in the absence of interfering signals which may adversely affect the measurement. The frequency deviation signal output by receiver 222 is integrated by integrator 242, and the output of integrator 242, which represents the dependence of variations in the output intensity of laser diode 212 with variations in frequency deviation signal output by receiver 222, is input via an adder to loop filter 218 in order to reduce said frequency variations.

In the measurement step illustrated in FIG. 5, step, the output signal from the integrator 242 is held constant by applying a zero volt signal to its input, and the sensor 204 is placed in a test fluid. The sensor chip 204 is then irradiated, and the frequency deviation signal output by receiver 222 indicates the presence and/or concentration of the relevant biomolecule on the sensor 204.

It will be appreciated by persons skilled in the art that the above embodiments have been described by way of example only, and not in any limitative sense, and that various alterations and modifications are possible without departure from the scope of the invention as defined by the appended claims.

1. An apparatus for detecting the presence and/or concentration of a predetermined substance on a sensor adapted to emit electromagnetic radiation of at least one first frequency in response to irradiation by electromagnetic radiation of at least one second frequency such that at least one said first frequency is dependent upon the presence and/or concentration of said predetermined substance, the apparatus comprising:
a radiation source for irradiating a sensor with electromagnetic radiation;
a receiver for receiving electromagnetic radiation emitted by said sensor;
detector means for providing an output signal dependent upon the change in at least one said first frequency caused by the presence and/or changes in concentration of said predetermined substance on the sensor; and adjustment means for reducing dependency of said output signal on the output intensity of said radiation source.

2. An apparatus according to claim 1, wherein the adjustment means is adapted to adjust said detector means to adjust at least one said first frequency corresponding to said output signal.

3. An apparatus according to claim 1, wherein the adjustment means is adapted to adjust said output signal.

4. An apparatus according to claim 1, wherein the adjustment means is adapted to adjust the output intensity of said radiation source.

5. An apparatus according to claim 1, wherein the adjustment means is adapted to provide an adjustment signal representing dependency of said output signal on the output intensity of said radiation source.

6. An apparatus according to claim 1, wherein the adjustment means is adapted to suppress fluctuations in said output signal.

7. An apparatus according to claim 1, wherein the adjustment means includes first integrating means for integrating said output signal.

8. An apparatus according to claim 1, wherein the adjustment means comprises second integrating means for integrating a signal representing variations in said output signal with the output intensity of said radiation source.

9. An apparatus according to claim 1, further comprising first stabilising means for reducing fluctuations in the frequency of the signal of maximum intensity detected by said detector means.

10. An apparatus according to claim 1, wherein further comprising second stabilising means for reducing fluctuations in the frequency of the radiation of maximum intensity output by said radiation source.

11. An apparatus according to claim 1, wherein the receiver includes an antenna and a radio frequency receiver.

12. A measurement system comprising an apparatus according to claim 1 and a sensor adapted to emit electromagnetic radiation of at least one first frequency in response to irradiation by means of said radiation source.

13. A method for determining the presence and/or concentration of a predetermined substance on a sensor adapted to emit electromagnetic radiation of at least one first frequency in response to irradiation by electromagnetic radiation of at least one second frequency such that at least one said first frequency is dependent upon the presence and/or concentration of said predetermined substance, the method comprising:
irradiating a sensor with electromagnetic radiation; receiving electromagnetic radiation emitted by said sensor; providing an output signal dependent upon the change in at least one said first frequency caused by the presence and/or changes in concentration of said predetermined substance on the sensor; and reducing dependency of said output signal on the output intensity of said radiation source.

14. A method according to claim 13, comprising adjusting at least one said first frequency corresponding to said output signal.

15. A method according to claim 13, comprising adjusting said output signal.

16. A method according to claim 13, comprising adjusting the output intensity of said electromagnetic radiation irradiating said sensor.

17. A method according to claim 13, further comprising providing an adjustment signal representing dependency of said output signal on the output intensity of said electromagnetic radiation irradiating said sensor.

18. A method according to claim 13, further comprising reducing fluctuations in said output signal.

19. A method according to claim 13, including integrating said output signal.

20. A method according to claim 13, further comprising reducing fluctuations in the frequency of the signal of maximum intensity of detected electromagnetic radiation emitted by the sensor.

21. A method according to claim 13, further comprising reducing fluctuations in the frequency of the radiation of maximum intensity irradiating the sensor.
